(19) United States
(12) Patent Application Publication
(10) Pub. No.: US 2008/0079166 A1
(43) Pub. Date: Apr. 3, 2008

(54) Managing forces of semiconductor device layers

(76) Inventors: Kevin J. Lee, Beaverton, OR (US); Subhash Joshi, Hillsboro, OR (US); Angelo Kandas, Portland, OR (US); Everett Branderhorst, Portland, OR (US); Rohit Grover, Hillsboro, OR (US); Tzuen-Luh Huang, Portland, OR (US)

Correspondence Address: LEE & HAYES, PLLC, P.O. BOX 52050, MINNEAPOLIS, MN, 55402, US

(21) Appl. No.: 11/540,200

(22) Filed: Sep. 29, 2006

(51) Int. Cl. H01L 23/48

(52) U.S. Cl. 257/762

(57) ABSTRACT

Embodiments of semiconductor devices and methods of making such devices are presented herein.

### BACKGROUND

Semiconductor devices, which may comprise microprocessors, integrated circuits, central processing units, or the like, can be used to interconnect one or more devices or perform one or more operations. When fabricating such semiconductor devices, multiple devices are typically processed simultaneously on a wafer. Automated machines may handle the wafers containing the semiconductor devices during the fabrication process. In some instances, however, layers applied when forming the semiconductor devices may cause the wafer to bow, making it unsuitable for handling by the automated machines.

### BRIEF DESCRIPTION OF THE DRAWINGS

FIG. 1 is a diagrammatic side sectional view of a semiconductor device processed in accordance with an embodiment.

FIG. 2 is a diagrammatic top view of a semiconductor device processed in accordance with an embodiment.

FIG. 3 is a diagrammatic side sectional view of a substrate comprising a semiconductor layer, in accordance with an embodiment.

FIG. 4 is a diagrammatic side sectional view of a substrate comprising a semiconductor layer and a passivation layer, in accordance with an embodiment.

FIG. 5 is a diagrammatic side sectional view of a semiconductor device processed in accordance with an embodiment.

FIG. 6 is a flow diagram that illustrates acts in accordance with an embodiment.

FIG. 7 is another flow diagram that illustrates acts in accordance with an embodiment.

FIG. 8 is a diagram that illustrates an exemplary system in which semiconductor devices formed in accordance with the embodiments described herein can be used, in accordance with an embodiment.

### DETAILED DESCRIPTION

In the discussion that follows, specific implementation examples and methods are provided under the headings “Implementation Examples” and “Exemplary Methods”. It is to be appreciated and understood that such implementation examples and exemplary methods are not to be used to limit application of the claimed subject matter to only these examples. Rather, changes and modifications can be made without departing from the spirit and scope of the claimed subject matter.

Implementation Examples

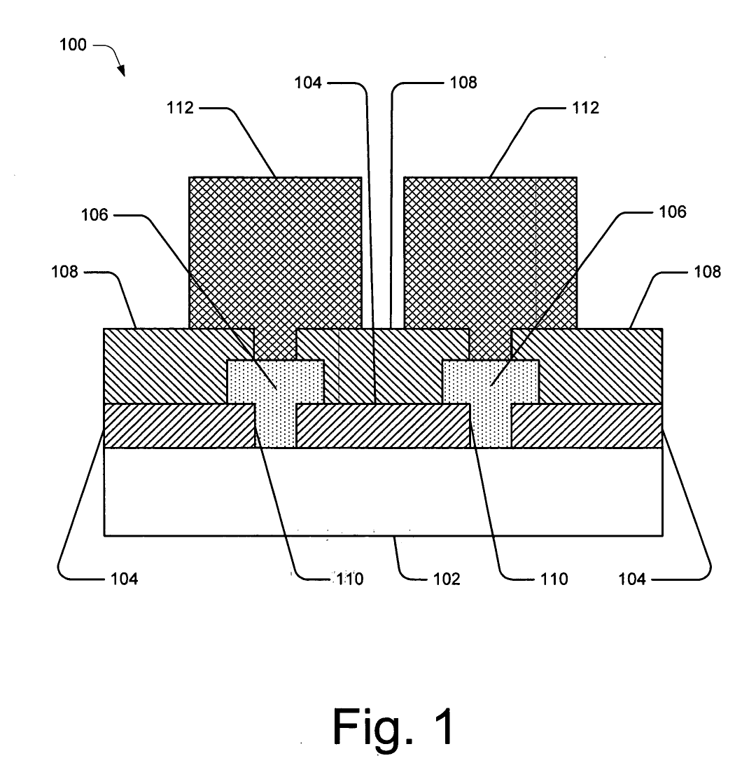

FIG. 1 depicts a semiconductor device 100 comprising a substrate 102, a passivation layer 104, a conductive layer 106, and a polymer layer 108. Substrate 102 may comprise a semiconductor material or layer and may, in some embodiments, comprise a wafer. In some instances, substrate 102 may comprise silicon. Substrate 102 may also include one or more additional layers, such as front end layers and back end layers. Front end layers may include one or more transistors or the like, while back end layers may include wiring of the semiconductor device 100. Multiple other layers may be included in substrate 102, such as one or more insulating layers, barrier layers, conductive or metal layers, contact layers, oxide layers, salicide layers, or the like.

In some implementations, passivation layer 104 may substantially cover substrate 102. Furthermore, it may be adjacent to substrate 102 or one or more layers may reside there between. Passivation layer 104 may be configured to serve a variety of functions. For example, passivation layer 104 may provide a hermetic seal to protect one or more layers in semiconductor device 100 from contamination from the surrounding environment. Such contamination may include ionic contaminates, moisture, or particles in the environment. Passivation layer 104 may, for example, protect substrate 102 and transistors located within substrate 102. Such protection may, in some instances, provide electrical stability to semiconductor device 100 and may thereby prevent the degradation of transistor performance.

Passivation layer 104 may comprise a material suitable to fulfill one or more of such layer's functions. In some instances, passivation layer may comprise a dielectric material, including an oxide or a nitride. Specific yet non-limiting examples include silicon nitride, silicon oxide, silicon dioxide, silicon carbide, silicon oxynitride, or the like.

Passivation layer 104 may further include one or more vias 110 to connect one or more layers of semiconductor device 100. In some instances, vias 110 may serve to connect conductive layer 106 and substrate 102.

Conductive layer 106 may comprise a conductive material, such as a metal or the like. For example, conductive layer 106 may comprise a thick metal layer of copper, aluminum, silver, or gold. Conductive layer 106 may be configured to serve a variety of functions, including to route electrical signals within semiconductor device or to provide better power distribution across a die, upon which substrate 102 may attach. Such electrical signals may include input/output signals, power connections and/or ground connections. Conductive layer 106 may also be configured to serve some thermo-mechanical benefits. If conductive layer 106 comprises a thick metal layer, this thick metal layer may reduce localized areas of high stress on substrate 102 in some instances. The die, for example, may be soldered to a printed circuit board (PCB) or the like during fabrication of an electrical circuit. After soldering, stress may result on one or more bumps which may attach to conductive layer 106. This stress may result from the two soldered components being made from materials with different coefficients of thermal expansion. This stress could cause the die to fracture if not for conductive layer 106, which again may reduce such localized stress and therefore avoid fracture of the die.

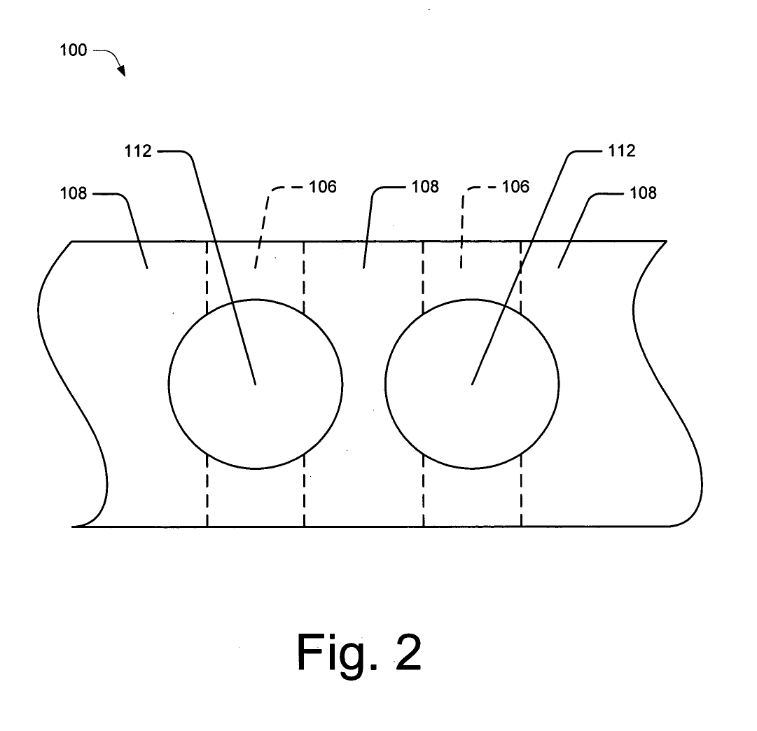

Referring back to FIG. 1, conductive layer 106 may substantially cover substrate 102. It may reside adjacent to substrate 102, or one or more layers may exist there between. Furthermore, conductive layer 106 may be patterned on semiconductor device 100 in a plurality of different ways. The resulting pattern may define a pattern density, which may be the amount of surface area of substrate 102 that conductive layer 106 covers, and further, may refer to an amount of surface area in a given location of the substrate that is covered by conductive layer 106. For instance, if a conductive layer 106 does not reside on substrate 102, then the pattern density would be 0%. Conversely, if conductive layer 106 completely covers substrate 102, then the pattern density would be 100%. Reference is made to FIG. 2, which depicts a top view of semiconductor device 100 and shows an exemplary pattern density. Pattern density management may be utilized in some embodiments to manage one or more forces on semiconductor device 100, as described in more detail below.

As mentioned above, conductive layer 106 may further comprise or contact one or more bumps 112. Bumps 112 may route electrical signals to or from semiconductor device 100, or may connect semiconductor device 100 to other components of an electrical circuit. Such electrical signals may again comprise input/output signals, power connections and/or ground connections. In some instances, bumps 112 may comprise a metal such as copper, although other suitable metals may be used. In other implementations, bumps 112 may reside directly adjacent to conductive layer 106, although other layers may also exist there between.

As stated above, semiconductor device 100 may include polymer layer 108. Polymer layer 108 may be configured to serve a variety of functions, such as to protect or insulate conductive layer 106. In some instances, polymer layer 108 may provide a buffer coat covering substrate 102. Polymer layer 108 may reside adjacent to conductive layer 106, or other layers may reside there between. As depicted, polymer layer 108 may leave bumps 112 exposed so as to allow for electrical routing of semiconductor device 100.

Polymer layer 108 may comprise one or more of a material suitable to fulfill one or more of the layer's functions. For example, polymer layer 108 may comprise a dielectric material, which may be a spin-on dielectric material or a buffer coat material. More specifically, non-limiting examples of suitable materials include polyamides such as aramids, phenolic resins such as novolak resins and polyhydroxystyrenes (PHS), Benzocyclobutene (BCB), polyacrylate, polymethacrylate, alicyclic polymers such as polynorbomenes, certain epoxies, certain silicones, polybenzoxazole, polybenzimidazole, polyetherimide, polyhydantoin, certain polycarbonates and certain polyesters.

In forming semiconductor device 100, passivation layer 104 may be deposited onto substrate 102. Passivation layer 104 may substantially cover substrate 102 or may instead cover a portion. Furthermore, passivation layer 104 may reside adjacent to substrate 102 or one or more other layers may reside there between. Passivation layer 104 may be deposited in a number of ways, including by chemical vapor deposition (CVD). More specifically, in some implementations passivation layer 104 may be deposited by plasma enhanced CVD techniques. As such, passivation layer 104 may substantially cover one side of substrate 102.

Conductive layer 106 may also be deposited onto substrate 102. Again, conductive layer 106 may substantially cover substrate 102 or may instead cover a portion. Furthermore, conductive layer 106 may reside adjacent to substrate 102 or one or more layers may reside in between, such as passivation layer 104. Conductive layer 106 may be deposited in a number of ways, including electroplating processes.

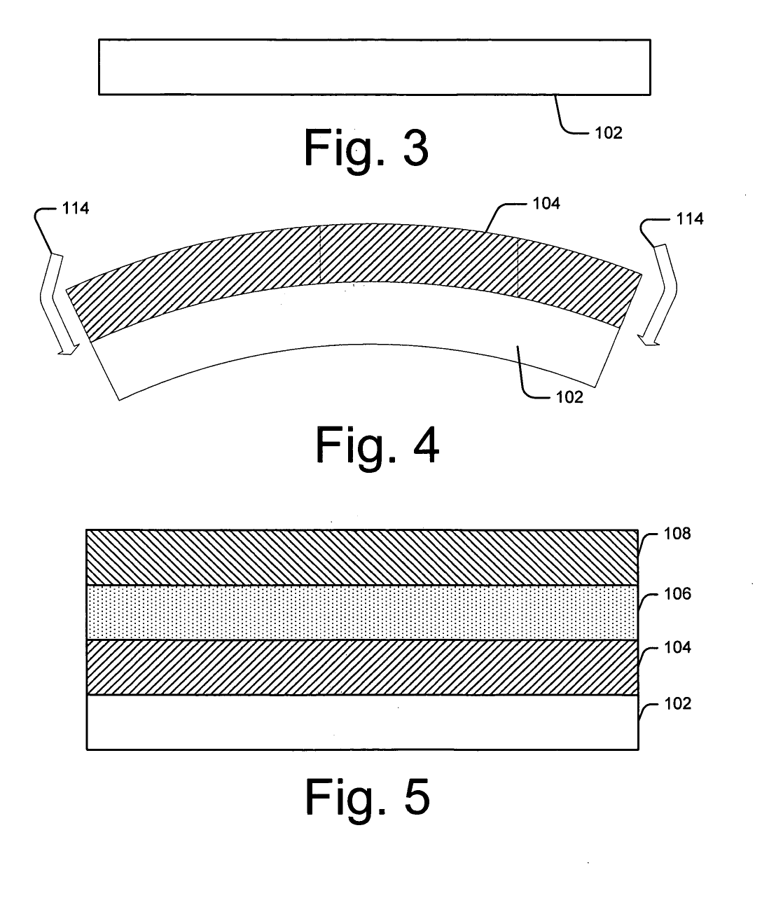

Referring to FIG. 3, substrate; 102 may initially be relatively flat before application of passivation layer 104. Substrate 102, however, could also be bowed in a certain direction, possibly a downward direction (i.e., “edge down”), such as “away” from layers that are to be deposited thereon. In some instances, substrate 102 may initially edge down by approximately 100 microns. Passivation layer 104 may be applied in a manner so as to maintain the relative flatness of substrate 102, or so as to maintain any slight bow that substrate 102 may initially have. If passivation layer 104 is deposited in this manner, however, then a substantially upward bow may result in semiconductor device 100 at some point of the fabrication process, which is described in greater detail below. As previously described, if semiconductor device 100 becomes “edged up” in this manner by more than an amount tolerated by automated machines used to process the semiconductor device 100, these machines may be unable to properly handle semiconductor device 100.

After passivation layer 104 is deposited in a manner so as to maintain the relative flatness of substrate 102, conductive layer 106 may be deposited and may substantially cover substrate 102 and/or passivation layer 104. Polymer layer 108 may then be deposited and may also substantially cover substrate 102, passivation layer 104, and/or conductive layer 106.

Polymer layer 108, and hence semiconductor device 100, may then be cured so as to harden or toughen polymer, layer 108 by cross-linking polymer chains. For example, semiconductor device 100 may be cured for a certain time period and at certain temperatures. During and after curing, physical characteristics of polymer layer 108 may change. Polymer layer 108, for instance, may shrink during cure and may become permanently deformed after cooling. This shrinkage and deformation may stress outer portions or edges of semiconductor device 100, and more particularly substrate 102. If polymer layer 108 resides on top of substrate 102, then polymer layer 108 may create a tensile force on the edges of substrate 102 that may cause the edges of semiconductor device 100 to bow upwards “away” from the substrate 102.

Certain physical characteristics of conductive layer 106 may also change during cure. For example, a grain structure of conductive layer 106 may enlarge during cure of semiconductor device 100. Again, if conductive layer 106 resides on top of substrate 102, then conductive layer 106 may also create a tensile force on the edges of semiconductor device 100 that may cause the edges of semiconductor device 100 to bow upwards away from the substrate 102. Thus, like the affects of curing previously described, these tensile forces may result in a semiconductor device that is substantially edged up, which may render downstream automated machines used, in the fabrication process incapable of handling semiconductor device 100.

Reference is thus made to FIGS. 3 and 4. Again, FIG. 3 depicts a flat or substantially flat substrate 102. FIG. 4 depicts substrate 102 and passivation layer 104. Alternatively, conductive layer 106 could first be deposited on substrate 102 and could potentially serve the bowing or stressing function described below in regards to passivation layer 104.

As illustrated in FIG. 4, passivation layer 104 may be deposited so as to create a bow in substrate 102, which may be in a downward direction. In other words, deposition of passivation layer 104 in this manner may cause substrate 102 to become bowed edged down. Substrate 102 may be substantially bowed edged down in some implementations. For example, substrate 102 may be intentionally bowed edged down approximately 450 microns. In some instances, deposition of passivation layer 104 may create a compressive force on edges of substrate 102, which may result in the above-described downward bow. This compressive force is represented by arrow 114 in FIG. 4.

Furthermore, creating this bow in substrate 102 may substantially counteract the tensile forces created by conductive layer 106 and/or polymer layer 108, which may pull the edges of substrate 102 upward as described above. In some implementations, the compressive force created by passivation layer 104 may be substantially equal to the tensile forces created by conductive layer 106 and/or polymer layer 108, either singly or in summation. Furthermore, this compressive force may be approximately opposite in direction from one or more of the tensile forces.

Passivation layer 104 may be deposited in a plurality of ways so as to bow or create a compressive force on substrate 102. For example, various properties of passivation layer 104 or properties of its deposition may be adjusted so as to result in a bowed substrate 102. In some instances, such as when passivation layer 104 is deposited by plasma enhanced CVD, one or more tools used to deposit the material may be capable of adjusting some or all of the afore-mentioned properties. Depositing passivation layer 104 at a relatively high temperature before cooling passivation layer 104 and substrate 102 down to room temperature may realize some or all of the compressive force. This may result in a thermal stress that bows edges of substrate 102 downward. Bias and gas flows may also be adjusted so as to bow substrate 102.

Furthermore, built-in stresses may be created or captured in passivation layer 104 during its deposition onto substrate 102, which may also serve to create the compressive force. The structure of passivation layer 104 may be modified to achieve this result. For example, passivation layer 104 may be deposited so that the resulting passivation layer 104 has a very fine chemical composition or grain structure. In some instances, this may serve to capture built-in stresses after completion of deposition. Again, such stresses may result in a substrate 102 that is edged down. Also, it is noted that other characteristics of the deposition may be modulated to obtain bowed substrate 102.

After deposition of passivation layer 104, conductive layer 106 and/or polymer layer 108 may be deposited onto substrate 102 as discussed above. Before, during, or after cure conductive layer 106 and polymer layer 108 may either singly or in combination serve to pull edges of substrate 102 upward. As shown in FIG. 5, the resulting semiconductor device 100 may be flat or substantially flat, which may enable subsequent automated machines to properly handle semiconductor device 100. While FIG. 5 depicts that semiconductor device 100 is flat, it may also have an amount of bow that is within a tolerable range of the automated machines. In some implementations, it may be acceptable for substrate 102 to be bowed within the range of approximately 500 microns downward (e.g., semiconductor device 100 bows toward the substrate 102) and approximately 200 microns upward (e.g., semiconductor device bows away from the substrate 102).

In addition to the embodiments described above, multiple other embodiments may be used to create semiconductor devices with tolerable amounts of bow as described below. It is noted that all embodiments may be used either singly or in any combination.

For example, the bow of semiconductor device 100 may further be managed by controlling certain characteristics of conductive layer 106. In some instances, controlling these characteristics may result in a conductive layer 106 that demonstrates less of a force on edges of substrate 102. Again, this force may be tensile and may serve to pull upward on substrate 102. The type of deposition process chosen for conductive layer 106 may be controlled in some instances. For example, the deposition process may comprise a plating process or solution, and an appropriate plating process or solution may be chosen that results in a lesser amount of bow in substrate 102 when conductive layer 106 is cured or annealed. For example, a plating process that results in a fine-grained or very fine-grained deposit of conductive layer 106 may be chosen instead of a plating process that results in a larger-grained layer. Such a fine-grained plating process may result in a lesser force on edges of substrate 102 during any thermal cycling that may occur relative to a similar force created if a larger-grained process is used.

Furthermore, the patterning of conductive layer 106 may be designed, managed, or restricted so as to lessen the amount of upward force on edges of substrate 102 caused by conductive layer 106. Again, the force may be tensile and may tend to edge up semiconductor device 100 or substrate 102. As described above, the amount of surface area of substrate 102 covered by conductive layer 106 may define a pattern density. Furthermore, conductive layer 106 may be patterned in lines that run along substrate 102. Forces created on substrate 102 due to conductive layer 106 may be different along the length of these lines than along their breadth. In some instances, an upward force created by conductive layer 106 may be greater along the length of the line. Also, higher stresses or forces may exist where there is a higher density of conductive layer 106, which may result in localized differences among the bow of substrate 102.

A pattern density may therefore be designed so that resulting semiconductor device 100 can meet appropriate performance, quality, and reliability targets, while not having a pattern density that may result in a substantial force on edges of substrate 102 and, ultimately, a semiconductor device with an unacceptably high bow. Furthermore, a pattern layout may be chosen that may create a generally repeatable bow between different types of semiconductor devices or substrates. Such a layout may thus suit numerous different devices. As such, the pattern density may be kept within an appropriate range that enables the resulting device to be adequately handled by the automated machines used in the fabrication process. In some implementations, a suitable range may be between 60% and 80% of the surface area of substrate 102.

In still other embodiments, cure conditions for polymer layer 108 and semiconductor device 100 may be chosen so as to minimize any resulting bow while still meeting appropriate performance, quality, and reliability targets. These targets may include mechanical and thermal stability targets, as well as chemical resistance targets. As described, above, the curing process may result in a force on edges of substrate 102 that may be in an upward direction. In some instances, shrinkage of polymer layer 108 during cure may at least in part create this force, which may increase with higher temperatures. Thus, cure conditions may be selected to minimize this force and the resulting bow, with such conditions possibly including temperature and time. In some instances, appropriate maximum cure temperature conditions may be found within a range of between 200° C. and 300° C. Similarly, in some instances an appropriate length of cure time may be between 1.5 hours and 2.5 hours. A temperature of approximately 250° C. and a time of approximately 2 hours may also be appropriate in some instances.

Exemplary Methods

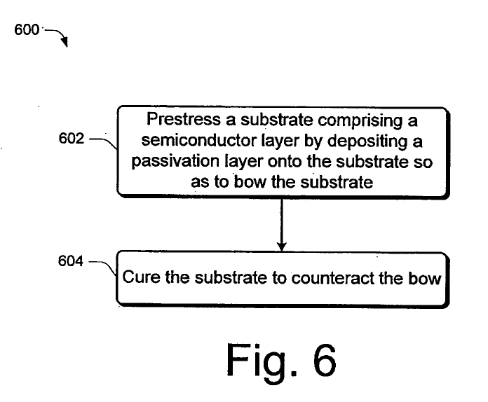

FIG. 6 is a flow diagram that illustrates a non-limiting exemplary method 600 in accordance with one embodiment described herein. Act 602 may comprise prestressing a substrate comprising a semiconductor layer by depositing a passivation layer onto the substrate so as to bow the substrate. Any suitable techniques can be utilized to deposit the passivation layer as discussed above. Act 604 may comprise curing the substrate to counteract the bow. Any suitable techniques can be utilized to cure the substrate as discussed above.

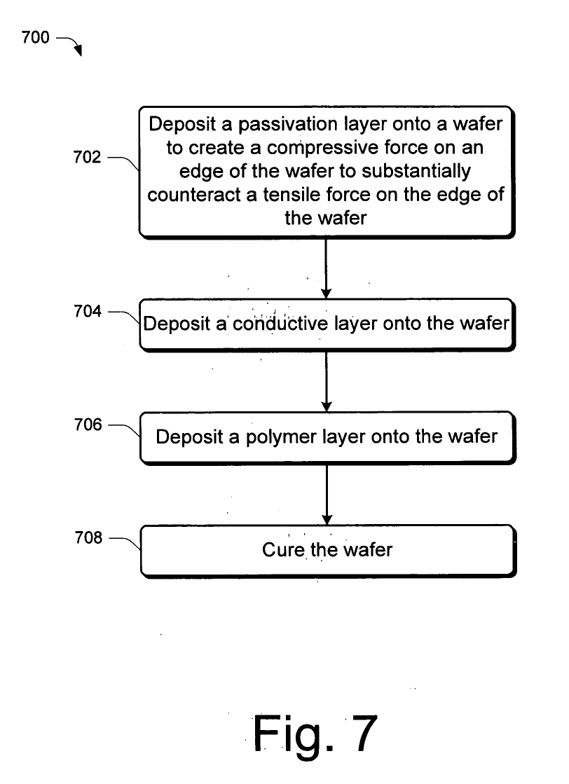

FIG. 7 is another flow diagram that also illustrates one non-limiting exemplary method 700 in accordance with one embodiment described herein. Act 702 may comprise depositing a passivation layer onto a wafer to create a compressive force on an edge of the wafer to substantially counteract a tensile force on the edge of the wafer. Any suitable techniques can be utilized to deposit the passivation layer. Act 704 may comprise depositing a conductive layer onto the wafer, which may be done using any suitable technique as discussed above. Act 706 may comprise depositing a polymer layer onto the wafer, which again may be done using any suitable techniques as described above. Act 708 may comprise curing the wafer, which also may be accomplished with use of any suitable techniques as described above.

Exemplary System

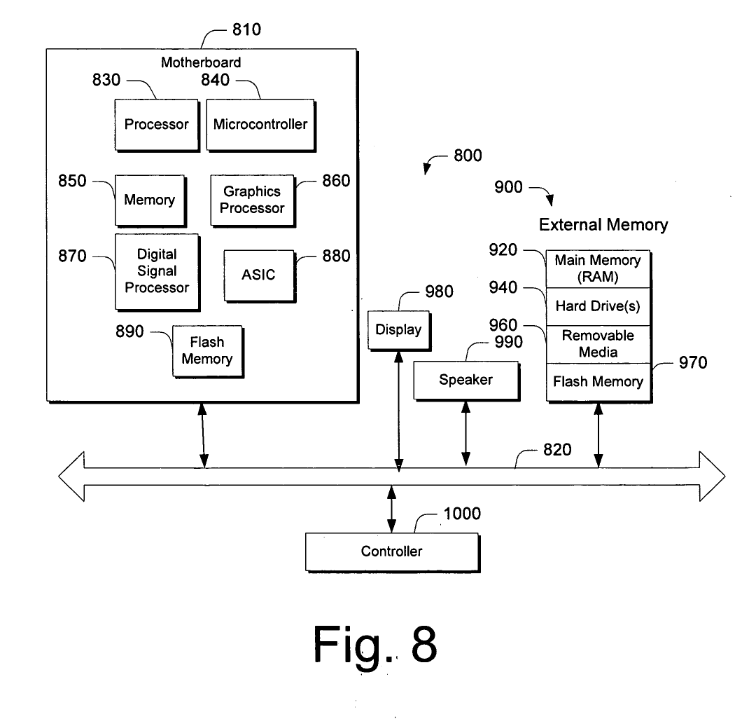

FIG. 8 depicts a block diagram of an exemplary electronic system 800 that can include semiconductor devices fabricated as described above. Such electronic system 800 may comprise a computer system that includes a motherboard 810 which is electrically coupled to various components in electronic system 800 via a system bus 820. System bus 820 may be a single bus or any combination of busses.

Motherboard 810 can include, among other components, one or more processors 830, a microcontroller 840, memory 850, a graphics processor 860 or a digital signal processor 870, and/or a custom circuit or an application-specific integrated circuit 880, such as a communications circuit for use in wireless devices such as cellular telephones, pagers, portable computers, two-way radios, and similar electronic systems and a flash memory device 890.

Electronic system 800 may also include an external memory 900 that in turn may include one or more memory elements suitable to the particular application. This may include a main memory 920 in the form of random access memory (RAM), one or more hard drives 940, and/or one or more drives that handle removable media 960, such as floppy diskettes, compact disks (CDs) and digital video disks (DVDs). In addition, such external memory may also include a flash memory device 970.

Electronic system 800 may also include a display device 980, a speaker 990, and a controller 1000, such as a keyboard, mouse, trackball, game controller, microphone, voice-recognition device, or any other device that inputs information into electronic system 800.

### CONCLUSION

The embodiments described above provide semiconductor devices with tolerable amounts of bow and also provide processes to achieve such devices. One process for achieving relatively flat semiconductor devices may include intentionally creating a compressive force on a substrate with the use of a passivation layer. Another process for minimizing an amount of bow comprises selecting an appropriate conductive layer plating process. Another process for minimizing bow comprises designing an appropriate pattern density layout. Yet another process for minimizing bow comprises selecting appropriate cure conditions for the semiconductor devices. All of the above-described embodiments may be used singly or in any combination with each other to create tolerably-bowed semiconductor devices.

Although the embodiments have been described in language specific to structural features and/or methodological acts, it is to be understood that the subject matter defined in the appended claims is not necessarily limited to the specific features or acts described. Rather, the specific features and acts are disclosed as exemplary forms of implementing the claimed subject matter.

What is claimed is:

1. An apparatus comprising:
a substrate comprising a semiconductor layer;
a passivation layer to create a first force on an edge of the substrate in a first direction; and
a polymer layer to create a second force on the edge of the substrate in a second direction, the second direction being approximately opposite the first direction.

2. An apparatus as described in claim 1, further comprising a conductive layer to create a third force on the edge of the substrate in a third direction, the third direction being approximately the same as the second direction.

3. An apparatus as described in claim 2, wherein the first force is approximately equal to the sum of the second and third forces.

4. An apparatus as described in claim 2, wherein the conductive layer comprises copper.

5. An apparatus as described in claim 2, wherein the conductive layer is patterned on the substrate and has a pattern density of between 60% and 80%.

6. An apparatus as described in claim 1, further comprising a bump to route electrical signals from the substrate to at least one other electrical component.

7. An apparatus as described in claim 1, wherein the passivation layer comprises a dielectric material.

8. An apparatus as described in claim 7, wherein the dielectric material comprises silicon nitride, silicon oxide, silicon dioxide, silicon carbide, or silicon oxynitride.

9. An apparatus as described in claim 1, wherein the polymer layer comprises a dielectric material.

10. An apparatus as described in claim 1, wherein the first force is created at least in part by selection of a deposition temperature, a passivation layer grain structure, a deposition power or a deposition bias.

11. A method comprising:
prestressing a substrate comprising a semiconductor layer by depositing a passivation layer onto the substrate so as to bow the substrate; and
curing the substrate to counteract the bow.

12. A method as described in claim 11, wherein the curing of the substrate results in a bow of between approximately 500 microns toward the substrate and away from the passivation layer and approximately 200 microns toward the passivation layer and away from the substrate.

13. A method as described in claim 11, further comprising depositing a conductive layer onto substrate.

14. A method as described in claim 11, wherein the passivation layer comprises silicon nitride, silicon oxide, silicon dioxide, silicon carbide, or silicon oxynitride.

15. A method as described in claim 11, further comprising coating the substrate with a polymer layer.

16. A method as described in claim 15, wherein the curing of the substrate comprises curing of the polymer layer to cause the polymer layer to shrink and thereby counteract the bow.

17. A method comprising:
depositing a passivation layer onto a wafer to create a compressive force on an edge of the wafer to substantially counteract a tensile force on the edge of the wafer created at least in part by curing a conductive layer and a polymer layer;
depositing the conductive layer onto the wafer;
depositing the polymer layer onto the wafer; and
curing the wafer.

18. A method as described in claim 17, wherein the depositing of the conductive layer onto the wafer is performed, at least in part, through a plating process that provides granularity sufficient to minimize a force created by the conductive layer when curing the wafer.

19. A method as described in claim 17, wherein the depositing of the conductive layer onto the wafer is performed, at least in part, through a plating process that substantially counteracts an amount of tensile force created when curing the wafer.

20. A method as described in claim 17, wherein the depositing of the conductive layer is performed to define a pattern layout for the conductive layer.

21. A method as described in claim 20, wherein the pattern layout for the metal layer is restricted to a density range of between approximately 60% and approximately 80%, the density range being defined by an amount of conductive material per an amount of wafer surface area.

22. A method as described in claim 17, wherein the curing incorporates one or more cure conditions that minimize an amount of tensile force created when curing the wafer.

23. A method as described in claim 22, wherein the one or more cure conditions comprise a temperature range of between approximately 200° C. and approximately 300° C. and a time range of between approximately 1.5 hours and approximately 2.5 hours.

24. A method as described in claim 22, wherein appropriate cure conditions comprise a temperature of approximately 250° C. and a time of approximately 2 hours.

25. A method as described in claim 17, wherein the deposition of the passivation layer comprises plasma enhanced chemical vapor deposition.

26. A method as described in claim 17, wherein the depositing of the passivation layer onto the wafer to create the compressive force is achieved at least in part by selecting one or more of a deposition temperature, a passivation layer grain structure, a deposition power or a deposition bias.

27. An electronic system comprising:
a semiconductor device configured to perform one or more operations, the processor comprising:
a semiconductor wafer;
a passivation layer to create a generally downward force on an edge of the wafer; and
one or more other layers to create a generally upward force on the edge of the wafer that substantially counteracts the generally downward force created by the passivation layer, the one or more other layers including a metal layer and a dielectric layer; and
a controller configured to provide input commands to perform at least one of the one or more operations.

28. An electronic system as described in claim 27, wherein the generally downward force is created at least in part by selection of one or more of a deposition temperature, a passivation layer grain structure, a deposition power or a deposition bias.

29. An electronic system as described in claim 27, wherein the metal layer comprises copper and wherein the metal layer is deposited onto the wafer, at least in part, through a plating process that provides granularity sufficient to minimize the generally upward force.

30. An electronic system as described in claim 27, wherein the metal layer defines a pattern layout restricted to a density range of between approximately 60% and approximately 80%, the density range being defined by an amount of metal material per an amount of wafer surface area
